(19) United States
(12) Patent Application Publication
(10) Pub. No.: US 2020/0279983 A1
(43) Pub. Date: Sep. 3, 2020

(54) LIGHT EMITTING DEVICE AND METHOD OF MANUFACTURING LIGHT EMITTING DEVICE

(71) Applicant: Toshiba Hokuto Electronics Corporation, Asahikawa-Shi (JP)

(72) Inventors: Naoki Takojima, Asahikawa (JP); Fumio Ueno, Tokyo (JP)

(73) Assignee: Toshiba Hokuto Electronics Corporation, Asahikawa-Shi (JP)

(21) Appl. No.: 16/803,303

(22) Filed: Feb. 27, 2020

(30) Foreign Application Priority Data
Mar. 1, 2019 (JP) 2019-037669

(51) Int. Cl. H01L 33/56; H01L 33/64; H01L 33/62

(52) U.S. Cl. CPC H01L 33/56; H01L 33/62; H01L 33/641

(57) ABSTRACT

A light emitting device, according to the present embodiment, has a first insulator, which is transparent to light, a first conductor layer, which is provided on a surface of the first insulator, a second insulator, which is transparent to light and arranged to oppose the first conductor layer, a light emitting element, which is arranged between the first insulator and the second insulator, and connected to the first conductor layer, and a third insulator, which is transparent to light and arranged between the first insulator and the second insulator, and the tensile storage elastic modulus of the third insulator is 1.0×10⁹ Pa or greater, up to 1.0×10¹⁰ Pa, at 0° C., and 1.0×10⁶ Pa or greater, up to 6.0×10⁸ Pa, at 130° C.

### CROSS-REFERENCE TO RELATED APPLICATIONS

This application is based upon and claims the benefit of priority from the prior Japanese Patent Application No. 2019-037669 filed in Japan on Mar. 1, 2019; the entire contents of which are incorporated herein by reference.

### FIELD

Embodiments of the present invention relate to a light emitting device and a method of manufacturing a light emitting device.

### BACKGROUND

A light emitting device that has two transparent insulating substrates and a plurality of LEDs arranged between the insulating substrates is known. A light emitting device of this kind is suitable for a display device that displays a variety of character strings, geometric figures and patterns and so forth, a display lamp and the like.

When the above light emitting device is used indoors, sufficient electrical reliability and mechanical reliability can be easily ensured. However, when the light emitting device is used in a harsh outdoor environment or used as a part of an automobile or the like, there is a need to provide a light emitting device that can withstand long-term use in an environment characterized by high temperature and high humidity.

### BRIEF DESCRIPTION OF THE DRAWINGS

FIG. 1 is a perspective view of a light emitting device;

FIG. 2 is an exploded perspective view of a light emitting device;

FIG. 3 is a side view of a light emitting module;

FIG. 4 is a plan view of a light emitting device;

FIG. 5 is a diagram to show a light emitting element connected to a conductor layer;

FIG. 6 is a perspective view of a light emitting element;

FIG. 7 is a side view of a flexible cable;

FIG. 8 is a diagram for illustrating how to connect a light emitting module and a flexible cable;

FIG. 9 is a diagram for illustrating how to manufacture a light emitting module;

FIG. 10 is a diagram for illustrating how to manufacture a light emitting module;

FIG. 11 is a diagram for illustrating how to manufacture a light emitting module;

FIG. 12 is a diagram to show the temperature dependency of tensile storage elastic modulus;

FIG. 13 is a diagram to show the temperature dependency of tangent loss;

FIG. 14 is a diagram to show the expansion coefficients and water absorption coefficients of samples;

FIG. 15 is a diagram to show the relationship between the junction temperature Tj and the number of good samples of light emitting elements;

FIG. 16 is a diagram to show results of a thermal cycle test;

FIG. 17 is a diagram to show the current-voltage characteristics of light emitting device;

FIG. 18 is a diagram to show the current-voltage characteristics of light emitting device;

FIG. 19 is a diagram to show a variation of a light emitting module;

FIG. 20 is a diagram to show a variation of a light emitting module;

FIG. 21 is a diagram to show a variation of a light emitting module;

FIG. 22 is a diagram to show an example of the use of a light emitting device;

FIG. 23 is a diagram to show a variation of a light emitting device; and

FIG. 24 is a diagram to show a variation of a light emitting module.

### DETAILED DESCRIPTION

In order to achieve the above object, according to the present embodiment, a light emitting device has a first insulator, which is transparent to light, a first conductor layer, which is provided on a surface of the first insulator, a second insulator, which is transparent to light and arranged to oppose the first conductor layer, a light emitting element, which is arranged between the first insulator and the second insulator, and connected to the first conductor layer, and a third insulator, which is transparent to light and arranged between the first insulator and the second insulator, and the tensile storage elastic modulus of the third insulator is 1.0×10⁹ Pa or greater, up to 1.0×10¹⁰ Pa, at 0° C., and 1.0×10⁶ Pa or greater, up to 6.0×10⁸ Pa, at 130° C.

Now, embodiments of the present invention will be described below with reference to the accompanying drawings. The following description will use an XYZ coordinate system, which consists of an X axis, a Y axis and a Z axis that are orthogonal to each other.

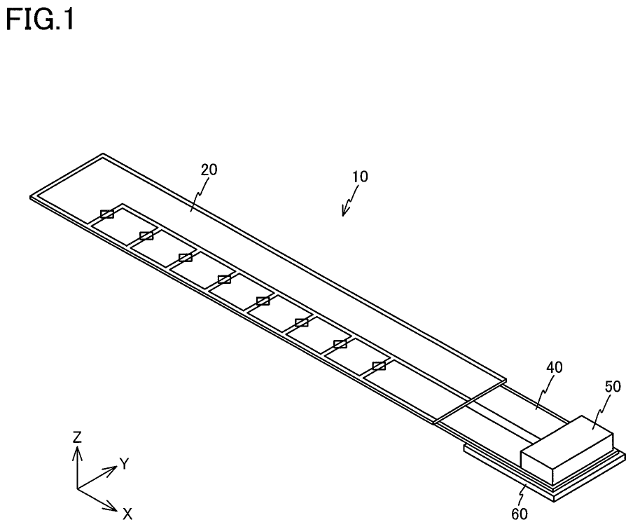

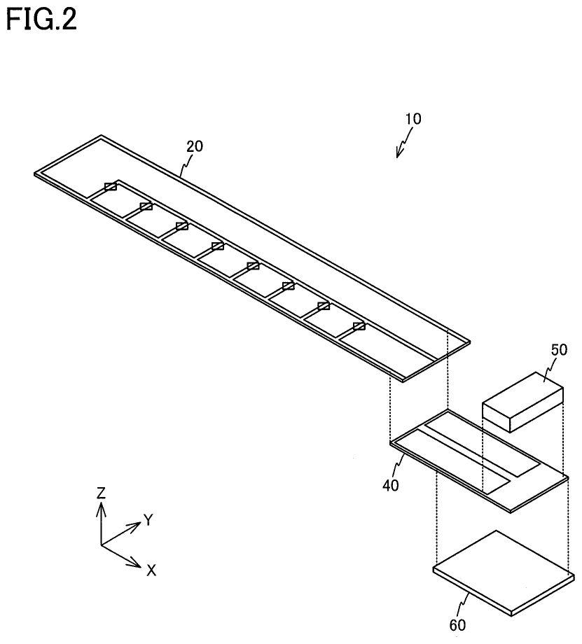

FIG. 1 is a perspective view of a light emitting device 10 according to the present embodiment. Also, FIG. 2 is an exploded perspective view of the light emitting device 10. As can be seen by referring to FIGS. 1 and 2, the light emitting device 10 has a light emitting module 20, whose longitudinal direction runs along the X-axis direction, a flexible cable 40 that is connected with the light emitting module 20, a connector 50 that is provided on the flexible cable 40, and a reinforcing plate 60.

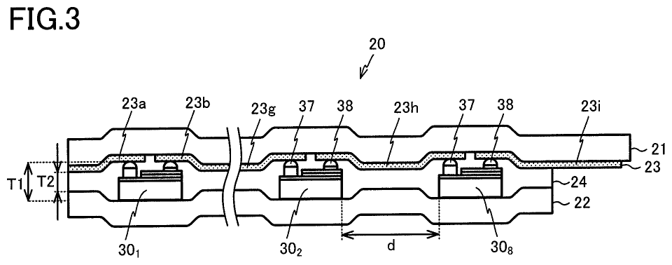

FIG. 3 is a side view of the light emitting module 20. As shown in FIG. 3, the light emitting module 20 has a pair of insulators 21 and 22, an insulator 24 that is formed between the insulators 21 and 22, and eight light emitting elements 30₁ to 30₈ that are arranged inside the insulator 24. The insulators 21 and 22 are film-like members, whose longitudinal direction runs along the X-axis direction. The insulators 21 and 22 are approximately 50 to 300 μm thick, and transparent to visible light. The total luminous transmittance of the insulators 21 and 22 is preferably about 5 to 95%. Note that the total luminous transmittance refers to the total luminous transmittance measured in conformity with the Japanese Industrial Standard JISK7375: 2008.

The insulators 21 and 22 are flexible, and their bending modulus of elasticity is 0 kgf/mm² or greater, up to 320 kgf/mm². Note that the bending modulus of elasticity is a value that is measured based on a method in conformity with ISO178 (JIS K7171: 2008). As for the materials for the insulators 21 and 22, polyethylene terephthalate (PET), polyethylene naphthalate (PEN), polycarbonate (PC), polyethylene succinate (PES), cyclic olefin resin (for example, ARTON (registered trademark) by JSR Corporation), acrylic resin and so forth may be used.

A conductor layer 23, approximately 0.05 μm to 10 μm thick, is formed in the lower surface of the insulator 21 (the surface on the −Z-side in FIG. 3) in the above pair of insulators 21 and 22. The conductor layer 23 is, for example, a vapor-deposited film, a sputtered film, and/or the like. Furthermore, the conductor layer 23 may be a metal film bonded with an adhesive.

When the conductor layer 23 is a vapor-deposited film, a sputtered film or the like, the conductor layer 23 is approximately 0.05 to 2 μm thick. When the conductor layer 23 is a bonded metal film, the conductor layer 23 is approximately 2 to 10 μm thick, or approximately 2 to 7 μm thick. In the conductor layer 23, fine particles of a non-transparent conductive material such as gold, silver, or copper may be attached to the insulator 21 in a mesh pattern. For example, a photosensitive compound of a non-transparent conductive material such as silver halide may be applied to the insulator 21 to form a thin film thereon, and this thin film may be subjected to exposure and development processes to form a conductor layer of a mesh pattern. Furthermore, the conductor layer 23 may be formed by applying a slurry containing fine particles of a non-transparent conductive material such as gold and copper in a mesh pattern by way of screen printing or the like.

Furthermore, for example, transparent conductive materials such as indium tin oxide (ITO), fluorine-doped tin oxide (FTO), zinc oxide, indium zinc oxide (IZO) and so forth can be used for the conductor layer 23. The conductor layer 23 can be formed by, for example, patterning the thin film formed on the insulator 21 by applying laser processing or etching process, based on a sputtering method, an electron beam evaporation method, and so forth. For example, the conductor layer 23 can also be formed by screen-printing a mixture of fine particles of a transparent conductive material, having an average particle diameter of 10 to 300 nm, and a transparent resin binder, on the insulator 21. Also, the conductor layer 23 can also be formed by forming a thin film made of the above mixture, on the insulator 21, and patterning this thin film by laser processing or photolithography.

The conductor layer 23 is preferably transparent so that the total luminous transmittance specified by JIS K7375 of the light emitting module 20 as a whole is 1% or more. If the total luminous transmittance of the light emitting module 20 as a whole is less than 1%, the light emitting points are no longer recognized as bright points. The transparency of the conductor layer 23 itself varies depending on its structure, but the total luminous transmittance is preferably in the range of 10 to 85%.

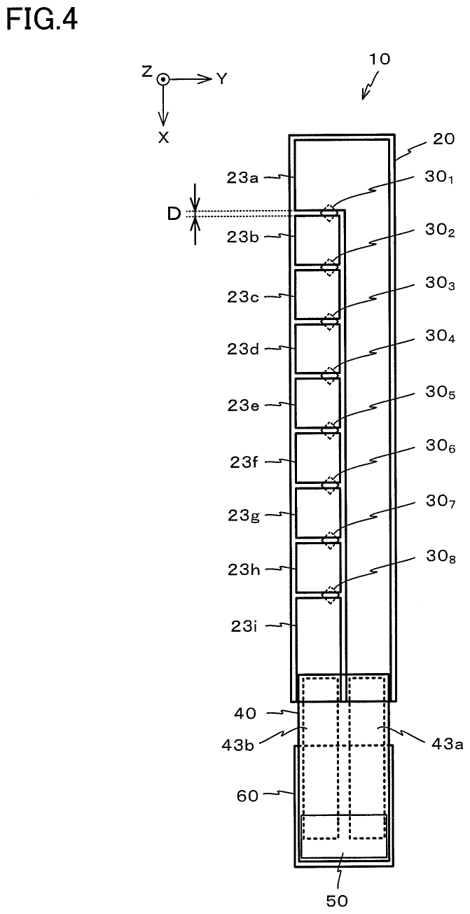

FIG. 4 is a plan view of the light emitting device 10. As can be seen by referring to FIG. 4, the conductor layer 23 is comprised of an L-shaped conductive circuit 23a, which is formed along the +Y-side outer edge of the insulator 21, and rectangular conductive circuits 23b to 23i, which are arranged along the −Y-side outer edge of the insulator 21. In the light emitting device 10, the distances D among the conductive circuits 23a to 23i are preferably 1000 μm or less, more preferably 200 μm or less, and even more preferably 100 μm or less.

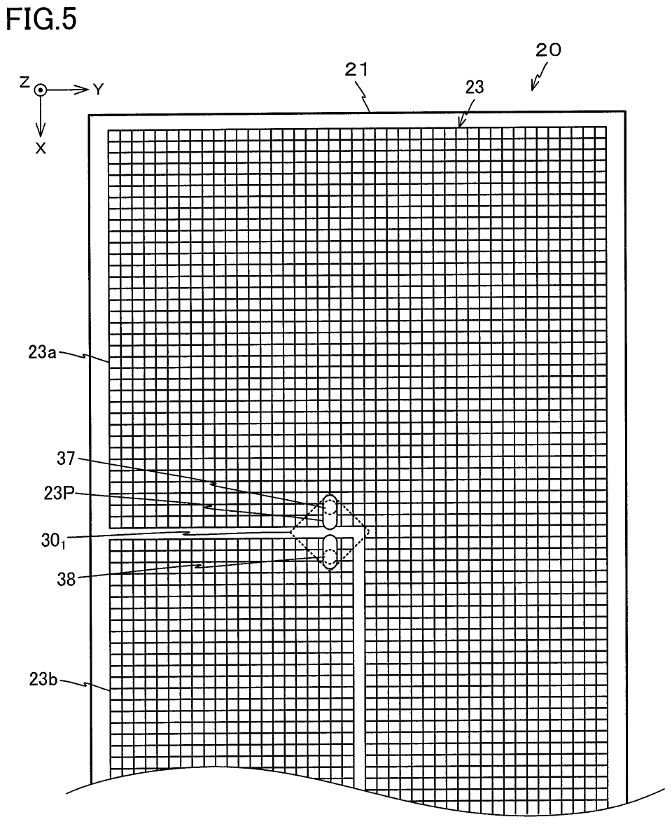

FIG. 5 is an enlarged view to show a part of the conductive circuits 23a and 23b. As shown in FIG. 5, the conductive circuits 23a to 23i assume a mesh pattern, formed with line patterns where the line width is approximately 5 μm. The line pattern that runs parallel to the X axis is formed roughly at 150-μm intervals, along the Y axis. Also, the line pattern that runs parallel to the Y axis is formed roughly at 150-μm intervals, along the X axis. In each of the conductive circuits 23a to 23i, a pad 23P, to which the electrodes of the light emitting elements 30₁ to 30₈ are connected, is formed.

In the light emitting device 10, the insulator 22 is shorter than the insulator 21 in the X-axis direction. Consequently, as can be seen by referring to FIG. 3 and FIG. 4, the +X-side ends of the conductive circuit 23a and the conductive circuit 23i that constitute the conductor layer 23 are exposed.

As shown in FIG. 3, the insulator 24 is an insulator that is formed between the insulator 21 and the insulator 22. The insulator 24 is made of, for example, an epoxy thermosetting resin. For example, the minimum melt viscosity VC1 of the insulator 24 before curing is preferably 10 to 10000 Pa·s in a range of 80 to 160° C. Also, the rate of change VR of the minimum melt viscosity VC1 before curing, up to the point where the temperature T1 (minimum softening temperature) is reached, is preferably 1/1000 or less (one thousandth or less). Furthermore, after the insulator 24 reaches the minimum melt viscosity by heating, that is, after curing, its Vicat softening temperature T2 is preferably in the range of 0 to 160° C., and its tensile storage elastic modulus EM in the range of 0 to 100° C. is preferably 0.01 to 1000 GPa.

The melt viscosity is a value that is determined by changing the temperature of the measurement object from 50° C. to 180° C., in accordance with the method described in JIS K7233. The Vicat softening temperature is a value that is determined under the conditions of a test load of 10 N and a heating rate of 50° C./hour, in accordance with A50 described in JIS K7206 (ISO 306: 2004). The tensile storage elastic modulus and the loss tangent are values determined based on a method in conformity with JIS K7244-1 (ISO 6721).

The tensile storage elastic modulus is measured by carefully polishing both sides of the light emitting module 20 little by little, removing the insulators 21 and 22, taking out the insulator 24 and using this insulator 24 as the measurement object. The tensile storage elastic modulus of this insulator 24 is a value determined based on a method in conformity with JIS K7244-1 (ISO 6721).

The thickness T2 of the insulator 24 is smaller than the height T1 of the light emitting elements 30₁ to 30₈ so as to place the conductor layer 23 and the bumps 37 and 38 in good contact with each other. The insulators 21 and 22 that are in close contact with the insulator 24 have curved shapes so that the parts where the light emitting elements 30₁ to 30₈ are arranged protrude outward and the parts between the light emitting elements 30₁ to 30₈ are depressed. Because the insulators 21 and 22 are bent in this way, the conductor layer 23 is pressed against the bumps 37 and 38 by the insulators 21 and 22.

The thickness T1 of the insulator 24 is 100 to 200 μm, and the thickness T2 is approximately 50 to 150 μm. Also, the thickness T1 of the insulator 24 is preferably 130 to 170 μm, and the thickness T2 is preferably 100 to 140 μm. Note that the thickness T1 is a size that depends on the thickness of the light emitting element 30. The thickness T1 is substantially equal to the sum of the thickness of the light emitting elements 30 and the thickness of the conductor layer 23. The thickness of the insulator 24 is in the range of about 40 to 1100 μm.

Furthermore, the insulator 24 fills the very small space between the upper surface of the light emitting elements 30₁ to 30₈ and the conductor layer 23, without a gap, in close contact with the electrodes 35 and 36 and the bumps 37 and 38.

Consequently, the electrical connectivity between the conductor layer 23 and the bumps 37 and 38 and the reliability thereof can be improved. Note that the insulator 24 is made of a light-transmitting or light-shielding material, which has a total luminous transmittance, as defined by JIS K7375, of 0.1% or more.

A resin sheet 241 contains thermosetting resins as main components, and becomes the insulator 24 when appropriate processing is performed, which will be described below. In this case, the raw materials of the insulator 24 may include other resin components if necessary. Epoxy resin, thermosetting acrylic resin, styrene resin, ester resin, urethane resin, melamine resin, phenol resin, unsaturated polyester resin, diallyl phthalate resin, urea-formaldehyde resin, alkyd resin, thermosetting polyimide and so forth can be used as thermosetting resin materials.

In addition, the resin sheet 241 can use thermoplastic resins as main component or sub-component materials. For the thermoplastic resin materials, polypropylene resin, polyethylene resin, polyvinyl chloride resin, acrylic resin, Teflon resin (registered trademark), polycarbonate resin, acrylonitrile butadiene styrene resin, polyamide resin polyimide resin and so forth can be used.

Among these, the epoxy resin shows excellent flowability during softening, adhesion after curing, weather resistance and so forth, in addition to transparency, electrical insulation, flexibility and the like, and therefore is an optimal raw material for a constituent material of the insulator 24. However, the insulator 24 may be made of resins other than epoxy resin.

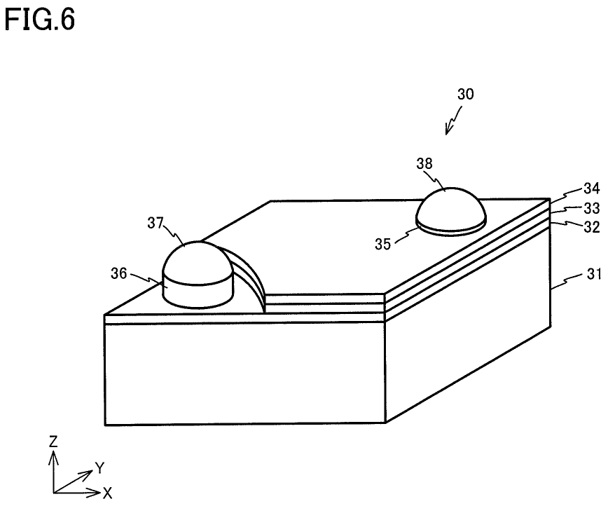

The light emitting element 30₁ is an LED chip. As shown in FIG. 6, the light emitting element 30₁ is an LED chip of a four-layer structure, comprised of a base substrate 31, an N-type semiconductor layer 32, an active layer 33, and a P-type semiconductor layer 34.

The base substrate 31 is a semiconductor substrate made of GaAs, Si, GaP, sapphire and the like. For the base substrate 31, one that is optically transparent may be used, so that light can be emitted from both upper and lower surfaces of the light emitting element 30, and from lateral directions. The N-type semiconductor layer 32, which has the same shape as the base substrate 31, is formed on the upper surface of the base substrate 31. Then, the active layer 33 and the P-type semiconductor layer 34 are laminated, in order, on the upper surface of the N-type semiconductor layer 32.

The active layer 33 is made of, for example, InGaN. Also, the P-type semiconductor layer is made of, for example, p-GaN. Note that the light emitting element 30 may have a double hetero (DH) structure or a multiple quantum well (MQW) structure. The active layer 33 and the P-type semiconductor layer 34, laminated on the N-type semiconductor layer 32, have a notch formed in the −Y-side and −X-side corner portion, and the surface of the N-type semiconductor layer 32 is exposed through the notch.

In the portion of the N-type semiconductor layer 32 that is exposed through the active layer 33 and the P-type semiconductor layer 34, an electrode 36, which is electrically connected with the N-type semiconductor layer 32, is formed. In addition, an electrode 35, which is electrically connected with the P-type semiconductor layer 34, is formed in the +X-side and +Y-side corner portion of the P-type semiconductor layer 34.

The electrodes 35 and 36 are made of copper (Cu) and gold (Au), and bumps 37 and 38 are formed on their upper surfaces. The bumps 37 and 38 are made of solder, and shaped like hemispheres. Metal bumps of gold (Au), a gold alloy, and so forth may be used instead of solder bumps. In the light emitting element 30₁, the bump 37 functions as a cathode electrode, and the bump 38 functions as an anode electrode.

Note that only one of the electrodes 35 and 36 of the light emitting element 30, or both of the electrodes 35 and 36, may be electrically connected to the conductor layer 23 via the bump 37 or the bump 38, or the electrodes 35 and 36 may be directly connected to the conductor layer 23 without the bumps 38 and 39.

Also, in the light emitting module 20, a light emitting element, in which a pair of electrodes 35 and 36 are separately provided on the upper and lower surfaces of the light emitting element, may be used. In that case, the conductor layer 23 is provided also on the surface of the insulator 22. In this case, bumps may be formed on electrodes connected to the insulator 21.

The light emitting element 30₁ configured as described above is, as shown in FIG. 5, arranged between the conductive circuits 23a and 23b, the bump 37 is connected to the pad 23P of the conductive circuit 23a, and the bump 38 is connected to the pad 23P of conductive circuit 23b.

The rest of the light emitting elements 30₂ to 30₈ also have the same configuration as the light emitting element 30₁. Then, the light emitting element 30₂ is arranged between conductive circuits 23b and 23c, and bumps 37 and 38 are connected to the conductive circuits 23b and 23c, respectively.

Following this, in a similar fashion, the light emitting element 30₃ is arranged over conductive circuits 23c and 23d. The light emitting element 30₄ is arranged over conductive circuits 23d and 23e. The light emitting element 30₅ is arranged over conductive circuits 23e and 23f. The light emitting element 30₆ is arranged over conductive circuits 23f and 23g. The light emitting element 30₇ is arranged over conductive circuits 23g and 23h. The light emitting element 30₈ is arranged over conductive circuits 23h and 23i. By this means, the conductive circuits 23a to 23i and the light emitting elements 30₁ to 30₈ are connected in series. In the light emitting module 20, the light emitting elements 30₁ to 30₈ are arranged roughly at 10-mm intervals.

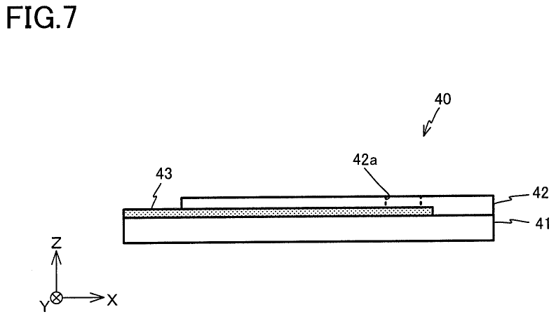

FIG. 7 is a side view of a flexible cable 40. As shown in FIG. 7, the flexible cable 40 is comprised of a base material 41, a conductor layer 43 and a cover lay 42.

The base material 41 is a rectangular member, whose longitudinal direction runs along the X-axis direction. This base material 41 is made of polyimide, for example, and a conductor layer 43 is formed on its upper surface. The conductor layer 43 is formed by patterning a copper foil that is stuck on the upper surface of polyimide. In the present embodiment, as shown in FIG. 4, the conductor layer 43 is comprised of two conductive circuits 43a and 43b.

Referring back to FIG. 7, the conductor layer 43, formed on the upper surface of the base material 41, is covered with the coverlay 42 that is bonded by vacuum thermo-compression. This coverlay 42 is shorter than the base material 41 in the X-axis direction. Consequently, the −X-side end parts of the circuit patterns 43a and 43b constituting the conductive circuits 43 are exposed. Also, an opening part 42a is provided in the coverlay 42, and the +X-side end parts of the conductive circuits 43a and 43b are exposed through this opening part 42a.

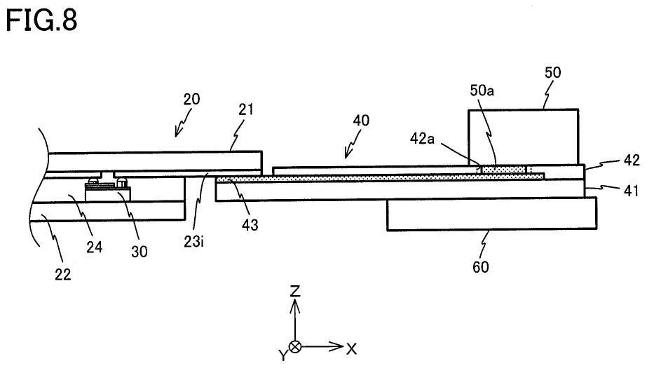

As can be seen by referring to FIG. 4 and FIG. 8, the flexible cable 40, configured as described above, is bonded to the light emitting module 20 in a state in which the conductive circuits 43a and 43b that are exposed through the coverlay 42 are in contact with the +X-side end parts of the conductive circuits 23a and 23i of the light emitting module 20.

As shown in FIG. 2, a connector 50 is a rectangular-parallelepiped component, and connected to a cable that is routed from a DC power source. The connector 50 is mounted on the upper surface of the +X-side end part of the flexible cable 40. When the connector 50 is mounted on the flexible cable 40, as shown in FIG. 8, a pair of terminals 50a of the connector 50 are connected, respectively, with the conductive circuits 43a and 43b constituting the conductor layer 43 of the flexible cable 40, through the opening part 42a provided in the coverlay 42.

As shown in FIG. 2, the reinforcing plate 60 is a rectangular member, whose longitudinal direction runs along the X-axis direction. The reinforcing plate 60 is made of, for example, epoxy resin or acrylic. This reinforcing plate 60 is, as shown in FIG. 8, attached to the lower surface of the flexible cable 40. Therefore, the flexible cable 40 can be bent between the −X-side end of the reinforcing plate 60 and the +X-side end of the light emitting module 20.

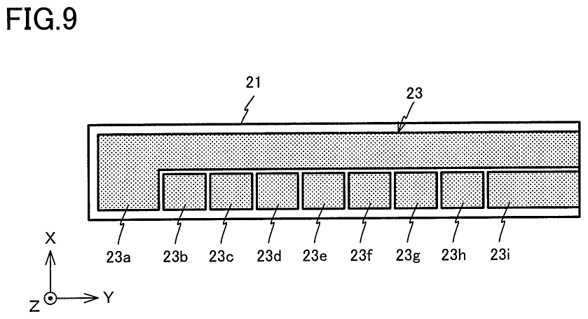

Next, a method of manufacturing the light emitting module 20 constituting the above-described light emitting device 10 will be described. First, as shown in FIG. 9, an insulator 21, which is made of PET, is prepared. Then, a conductor layer 23, which is comprised of conductive circuits 23a to 23i, is formed on the surface of the insulator 21. As for the method of forming the conductive circuits 23a to 23i, for example, a subtractive method, an additive method or the like can be used.

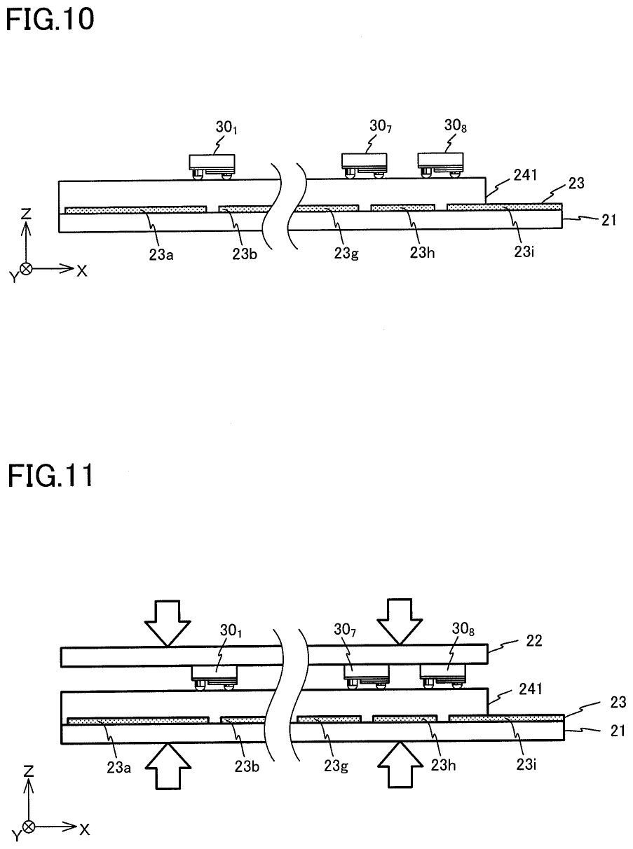

Next, as shown in FIG. 10, a resin sheet 241 is provided on the surface of the insulator 21, on which the conductive circuits 23a to 23i are formed. The thickness of this resin sheet 241 is substantially equal to the thickness of the light emitting element 30, or the thickness of the light emitting element 30 plus bumps 37 and 38. The resin sheet 241 is made of, for example, thermosetting resins. The resin sheet 241 may contain other resin components and the like if necessary. Advantages of using thermosetting resins include excellent reliability under high temperature and high humidity.

Epoxy resin, acrylic resin, styrene resin, ester resin, urethane resin, melamine resin, phenol resin, unsaturated polyester resin, diallyl phthalate resin, urea-formaldehyde resin, alkyd resin, thermosetting polyimide and the like can be used as thermosetting resins.

Furthermore, for the resin sheet 241, materials containing thermoplastic resins as main components can be used. Advantages of using thermoplastic resins include that they are resistant to mechanical shock, show little discoloration under high temperature and high humidity or when irradiated with ultraviolet rays, and are relatively inexpensive.

For the thermoplastic materials, polypropylene resin, polyethylene resin, polyvinyl chloride resin, acrylic resin, Teflon resin (registered trademark), polycarbonate resin, acrylonitrile butadiene styrene resin, polyamide resin, polyimide resin and so forth can be used.

That is, an appropriate resin sheet is selected depending on the application and environmental conditions. Among these, the epoxy resin shows excellent flowability during softening, adhesion after curing, weather resistance and so forth, in addition to transparency, electrical insulation, flexibility and the like, and therefore is an optimal raw material for a constituent material of the resin sheet 241. Obviously, the resin sheet 241 may be made of resins other than epoxy resin.

Next, the light emitting elements 30₁ to 30₈ are arranged on the resin sheet 241. At this time, the light emitting elements 30₁ to 30₈ are positioned such that the pads 23P of the conductive circuits 23a to 23i are located right below the bumps 37 and 38 of the light emitting element 30.

Next, as shown in FIG. 11, the insulator 22 is arranged on the upper surface side of the insulator 21.

Next, the insulators 21 and 22 are each heated and pressed in a vacuum atmosphere. By this means, first, the bumps 37 and 38 formed on the light emitting element 30 penetrate the resin sheet 241, reach the conductor layer 23, and are electrically connected to the conductive circuits 23a to 23i. Then, the resin sheet 241, having been heated and softened, is filled around the light emitting element 30 without a gap, so that the insulator 24 is obtained. In this way, the light emitting module 20 is completed.

As shown in FIG. 8, the flexible cable 40, to which the reinforcing plate 60 is attached, is connected to the light emitting module 20 manufactured as described above, and the connector 50 is mounted on this flexible cable 40, so that the light emitting device 10 shown in FIG. 1 is completed. With the light emitting device 10, when a DC voltage is applied to the conductive circuits 43a and 43b shown in FIG. 4 via the connector 50, the light emitting elements 30₁ to 30₈ that constitute the light emitting module 20 emit light.

The light emitting module 20 of the light emitting device 10 is structured so that the insulators 21 and 22, made of PET and/or the like, are bonded by means of the insulator 24. When the light emitting device 10 is used outdoors or used in a severe environment characterized by high temperature and high humidity, the deterioration over time progresses relatively quickly due to the impact of the temperature and humidity. Consequently, it is necessary to constitute the insulator 24 through an appropriate heating and pressing step, using raw materials that are robust to environments characterized by high temperature and high humidity.

In places where the temperature and humidity change a lot, the viscoelasticity of the insulator 24 also varies following changes in temperature. With the light emitting device 10, electrical coupling is established only between the bumps 37 and 38 of the light emitting elements 30₁ to 30₈ and the pads 23P of the conductive circuits 23a to 23i, over very small spaces on the order of several tens μm or less. Consequently, when the viscoelasticity of the insulator 24 changes, the electrical contact between the bumps 37 and 38 of the light emitting elements 30₁ to 30₈ held by the insulator 24 and the pads 23P of the conductive circuits 23a to 23i may be lost, and the light emitting elements 30₁ to 30₈ may be turned off. Therefore, it is necessary to select optimal resins as resins to constitute the insulator 24.

In addition, with the light emitting device 10, resins to have characteristics suitable to the environment of use may be used for the insulator 24. For example, when using the light emitting device 10 in an environment of 85° C., it is preferable that the relationship between the junction temperature Tj of the light emitting elements and the temperature T_{tan δmax} at which the loss tangent tan δ of the insulator 24 becomes the maximum fulfills the condition represented by the following equation:

T_{tan δmax}<1.65Tj−47.5

By using a resin with an expansion coefficient less than 21.3% in an environment in which the temperature is 85° C. and the humidity is 40% or greater, up to 85%, as an insulator 24, a highly reliable light emitting device 10 can be provided. Note that the resin's expansion coefficient complies with JIS K7197, and is a value measured by using humidity control-type thermomechanical analysis apparatus (TMA) of NETZSCH Japan K.K.

Also, while the light emitting elements 30₁ to 30₈ may be approximately 30 to 1000 μm thick, if the light emitting elements 30₁ to 30₈ are 90 to 300 μm thick, the insulator 24 is preferably 90 to 350 μm thick. The linear expansion coefficient of the insulator 24 is preferably 40 ppm/° C. or greater, up to 80 ppm/° C. When polyethylene or polystyrene is used as a material for the insulator 24, the Young's modulus is preferably 0.3 to 10 GPa, and, when epoxy is used as a material for the insulator 24, the Young's modulus is preferably about 2.4 GPa.

The elastic modulus of the insulator 24 is preferably 1900 to 4900 MPa. The haze of the insulator 24 is preferably 15% or less. In addition, b* of the insulator 24 is preferably less than 5. The luminous transmittance of the insulator 24 is preferably 30% or greater.

In the event a stress to bend the light emitting device 10 acts on the light emitting device 10 placed in a high-temperature (85° C.) environment, if the bending stress value of the insulator 24 is high, the stability of connection for holding the light emitting elements is ensured. On the other hand, if an excessive stress acts on the light emitting device 10, the insulator 24 is deformed plastically, and loses its stability of connection. Also, if the bending stress value of the insulator 24 is low, the insulator is easily deformed plastically by the stress, and loses its stability of connection.

When the absolute value of the rate of change of the bending stress in a low-temperature environment and the bending stress in a high-temperature environment is large, the stability of connection drops, and this holds not only when a stress acts directly on the light emitting device 10, but also when a thermal shock applies to the light emitting device 10, such as when the light emitting device 10 is taken out of a room in which the temperature is low, to outside where the temperature is high, for example. By contrast with this, when the absolute value of the rate of change of the bending stress in a low-temperature environment and the bending stress in a high-temperature environment is small, the stability of connection increases.

The thickness of the insulators 21 and 22 is preferably 30 μm or greater, up to 300 μm. Furthermore, the heat-resistant temperature of the insulators 21 and 22 is preferably 100° C. or higher. The elastic modulus is preferably 2000 or greater, up to 4100 MPa. The luminous transmittance is preferably 90% or greater. The thermal conductivity is preferably 0.1 to 0.4 W/m·k. The haze is preferably 2% or less. In addition, b* is preferably less than 2.

The thickness of the light emitting elements 30₁ to 30₈ is preferably 30 μm or greater, up to 1000 μm, and the length of one side of the light emitting elements 30₁ to 30₈ is preferably 30 μm or greater, up to 3000 μm.

The height of the bumps 37 and 38 of the light emitting elements 30₁ to 30₈ is 30 μm or greater, up to 100 μm before the thermo-compression bonding step in the manufacturing process of the light emitting device 10. After the thermo-compression bonding step, the height of the bumps 37 and 38 is 10 μm or greater, up to 90 μm. The height and width of the bumps 37 and 38 are preferably 30 μm or greater, up to 100 μm.

If the conductor layer 23 is too thick, cracks may be produced in the conductor layer 23 when the light emitting device 10 is bent. On the other hand, if the conductor layer 23 is too thin, the electrical resistance of the conductor layer 23 increases. Therefore, the thickness of the conductor layer 23 is preferably 10 μm or less.

Regarding the mesh pattern in which the conductor layer 23 is constituted, if the line width is wide, the transparency is lost. Therefore, the line width of the mesh pattern is preferably 20 μm or less. The luminous transmittance is preferably 50% or greater. On the other hand, regarding the mesh pattern, if the line width is narrow, the electrical resistance increases, which results in increased susceptibility to disconnection. Therefore, the sheet resistance value of the conductor layer 23 is preferably 300Ω/□ or less.

In addition, in order to determine what conditions of resin are optimal to provide materials for the insulator 24 constituting light emitting device 10 described above, samples were prepared for an embodiment of the light emitting device 10, and measured in a variety of ways. Hereinafter, an embodiment of the light emitting device 10 will be described.

### EXAMPLES

To illustrate the present example, light emitting devices 10A to 10D were prepared as samples, and a variety of tests were performed. A resin sheet 241 made of an epoxy thermosetting resin A with a relatively high thermosetting temperature was used as the insulator 24 to constitute the light emitting device 10A. A resin sheet 241 made of an epoxy thermosetting resin B was used as the insulator 24 to constitute the light emitting device 10B. A resin sheet 241 made of an epoxy thermosetting resin C was used as the insulator 24 to constitute the light emitting device 10C. A resin sheet 241 made of a polypropylene (PP) thermosetting resin D was used as the insulator 24 to constitute the light emitting device 10D.

Furthermore, a resin sheet 241 made of acrylic thermoplastic resin E was used as the insulator 24 to constitute the light emitting device 10E for a comparative example.

In the heating and pressing process of the insulators 21 and 22 constituting the light emitting devices 10A to 10E, the work space where the laminate shown in FIG. 11 was placed was made a vacuum space with a degree of vacuum of 5 kPa, and pressure was applied while the laminate was heated. The laminate was thermo-compression bonded in the vacuum atmosphere, so that the space between the insulator 21 and the insulator 22 was filled with the softened insulator 24 without a gap. Note that the vacuum atmosphere during the thermo-compression bonding is preferably 5 kPa or less.

Also, the insulators 21 and 22 of the light emitting devices 10A to 10E were 100 μm thick. The conductor layer 23 was made of copper and was 2 μm thick. The conductive circuits 23a to 23i assumed a mesh pattern, which was made of a line pattern with a line width of 5 μm and an arrangement pitch of 300 μm. The resin sheet 241 was 120 μm thick.

<<Tensile Storage Elastic Modulus/Loss Tangent>>

With the present embodiment, a number of samples were prepared for each of the five types of light emitting devices 10A to 10E. Then, light emitting devices were randomly selected from a plurality of light emitting devices, and part of the insulators 24 was taken out, and the temperature dependency of the tensile storage elastic modulus, the temperature dependency of loss tangent, and the water absorption coefficients were measured.

To be more specific, both sides of the light emitting modules 20 constituting the light emitting devices 10A to 10E were polished carefully, thereby removing the insulators 21 and 22, and taking out the insulators 24. Next, the insulators 24 that were taken out were cut into a size of 10 mm×50 mm, to prepare test pieces for each of the light emitting devices 10A to 10E. Then, using a DMA7100-type dynamic viscoelasticity automatic measuring device manufactured by Hitachi High-Technologies Corporation, the temperature dependency of the tensile storage elastic modulus and loss tangent of the test pieces was measured.

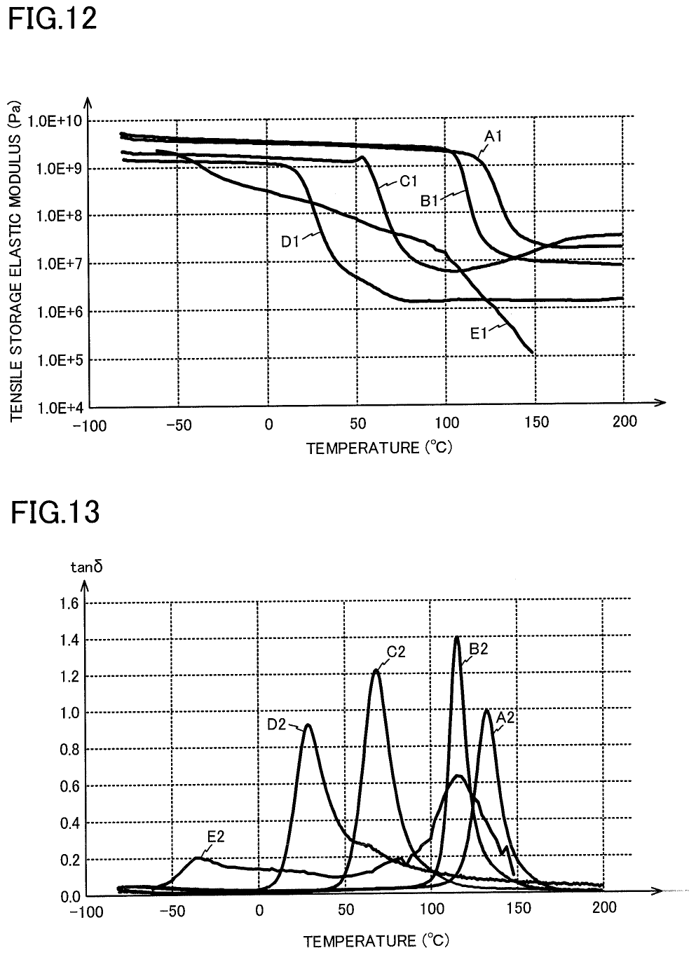

The measurement was carried out by increasing the temperature of the test pieces from −75 to 200° C., at a constant rate of 5° C. per minute, and sampling the test pieces at a frequency of 1 Hz. FIG. 12 is a diagram to show the temperature dependency of the tensile storage elastic modulus. Also, FIG. 13 is a diagram to show the temperature dependency of loss tangent tan δ.

<<Expansion Coefficient>>

Similarly, one light emitting device was randomly selected from a plurality of light emitting devices, and the insulator 24 was taken out. Next, the insulators 24 that were taken out were cut into a size of 10 mm×50 mm, to prepare test pieces for each of the light emitting devices 10A to 10E. Then, the expansion coefficient of the test pieces when the humidity was increased from 40% to 85% was measured in an environment in which the temperature was 85° C., using a humidity control-type thermomechanical analysis apparatus (TMA) of NETZSCH Japan K.K.

<<Water Absorption Coefficient>>

Similarly, one light emitting device was randomly selected from a plurality of light emitting devices, and the insulator 24 was taken out. Next, the insulator 24 that was taken out was cut into a size of 10 mm×30 mm, to prepare test pieces for each of the light emitting devices 10A to 10E. Then, using a constant temperature and humidity measuring instrument (PL-3J) manufactured by ESPEC CORP, the water absorption coefficient were measured from the weight of each test piece that was sufficiently dry, and the weight of each test piece having been placed in an environment with a temperature of 85° C. and a humidity of 85% for 24 hours.

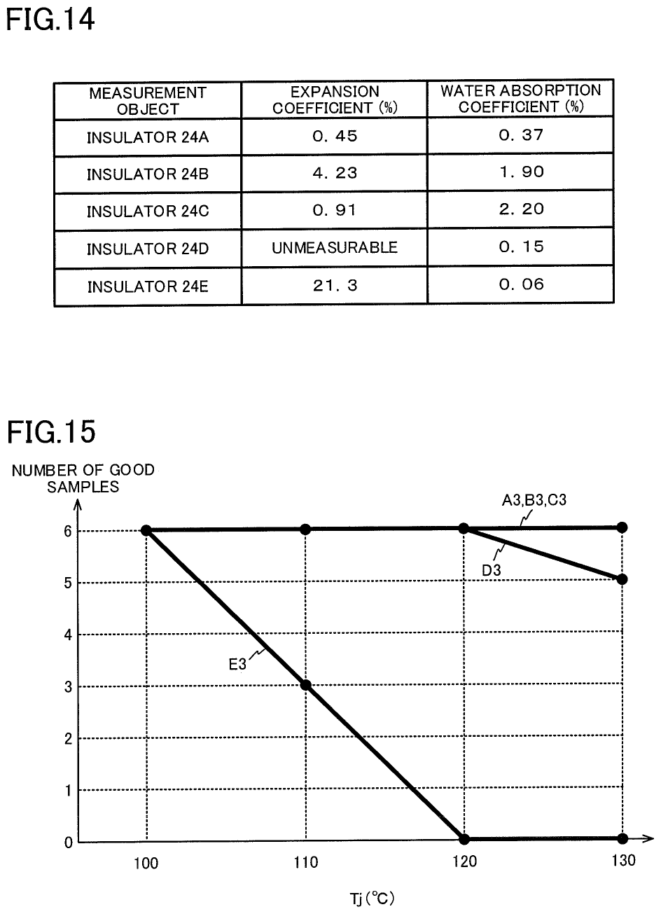

FIG. 14 shows a table to show the expansion coefficient and water absorption coefficient of each sample. Note that, with the light emitting device 10D, no expansion coefficient could be measured.

<<High-Temperature and High-Humidity Test>>

Next, the light emitting devices were subjected to a high-temperature and high-humidity test. In the high-temperature and high-humidity test, 24 light emitting devices 10A were selected out of a plurality of light emitting devices 10A, and these light emitting devices 10A were divided into four groups, each consisting of six light emitting devices. Then, the junction temperatures Tj of the light emitting devices 10A of each group were set to 100° C., 110° C., 120° C., and 130° C., respectively. Next, each light emitting device 10A was lit for 1000 hours in an environment in which the temperature was 85° C. and the humidity was 85%. When lighting the light emitting device 10A, each light emitting device 10A was bent so that the insulator 22 was located on the outside and the radius of curvature was 50 mm.

Similarly, for each of the light emitting devices 10B to 10E, 24 devices were selected from a plurality of light emitting devices 10B to 10E, and these light emitting devices 10B to 10E were each divided into four groups, each consisting of six light emitting devices. Then, the junction temperatures Tj of the light emitting devices 10B to 10E of each group were set to 100° C., 110° C., 120° C., and 130° C., respectively. Next, each light emitting device 10A was lit for 1000 hours in an environment in which the temperature was 85° C. and the humidity was 85%. When lighting the light emitting devices 10B to 10E, the light emitting devices 10B to 10E were all bent so that the insulators 22 were located on the outside and the radius of curvature was 50 mm.

As described above, a high-temperature and high-humidity test to light the light emitting devices 10A to 10E, 24 each, for 1000 hours was performed, and the number of light emitting devices 10A to 10E that kept lighting without problem was checked. FIG. 15 shows the results of the high-temperature and high-humidity test of each of the light emitting devices 10A to 10E. Graphs A3 to E3 show relationships between the numbers of good samples and the junction temperatures of the light emitting devices 10A to 10E, respectively. Also, for convenience, the environment in which the temperature is 85° C. and the humidity is 85% is also referred to as the “test environment”.

<<Thermal Cycle Test>>

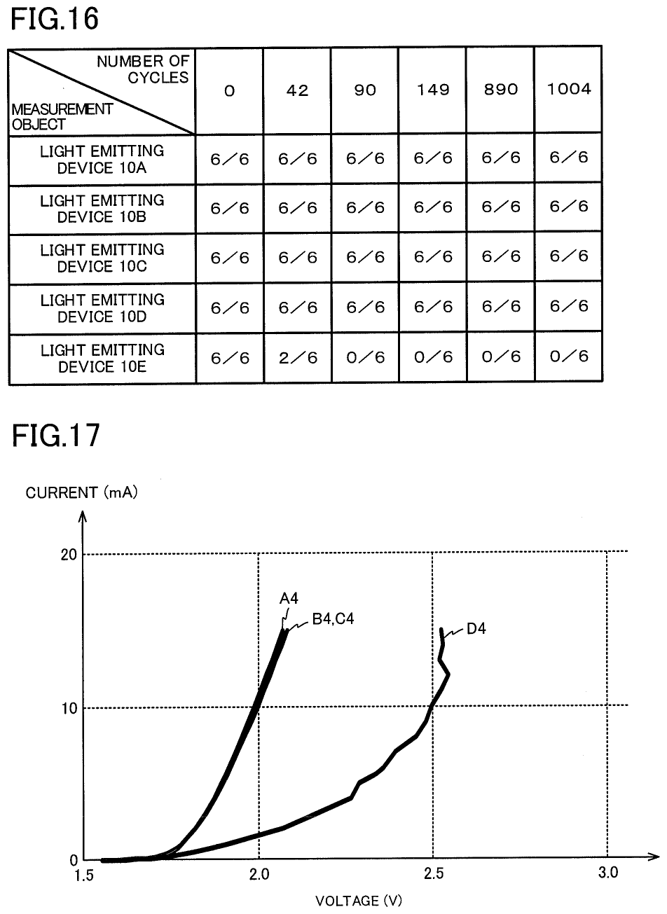

Furthermore, the light emitting devices 10A to 10E, six of each, were selected and subjected to a thermal cycle test. For the thermal cycle test, the light emitting devices 10A to 10E, six each, were provided unlit, and a test, in which 1 minute of exposure in an environment with a temperature of 25° C., 5 minutes of exposure in an environment with a temperature of −40° C., 1 minute of exposure in an environment with a temperature of 25° C., and 1 minute of exposure in an environment with a temperature of 110° C. constitute one cycle, was performed. Then, every time a predetermined cycle was complete, whether each light emitting device was lit was checked. FIG. 16 is a diagram to show the results of the thermal cycle test. In the table of FIG. 16, the denominator shows the number of light emitting devices 10A to 10E that were subjected to the test, and the numerator shows the number of good samples (light emitting devices that were lit).

Also, upon the thermal cycle test, not only the lighting state was checked per cycle, but also the current-voltage characteristics of the light emitting devices 10 were measured.

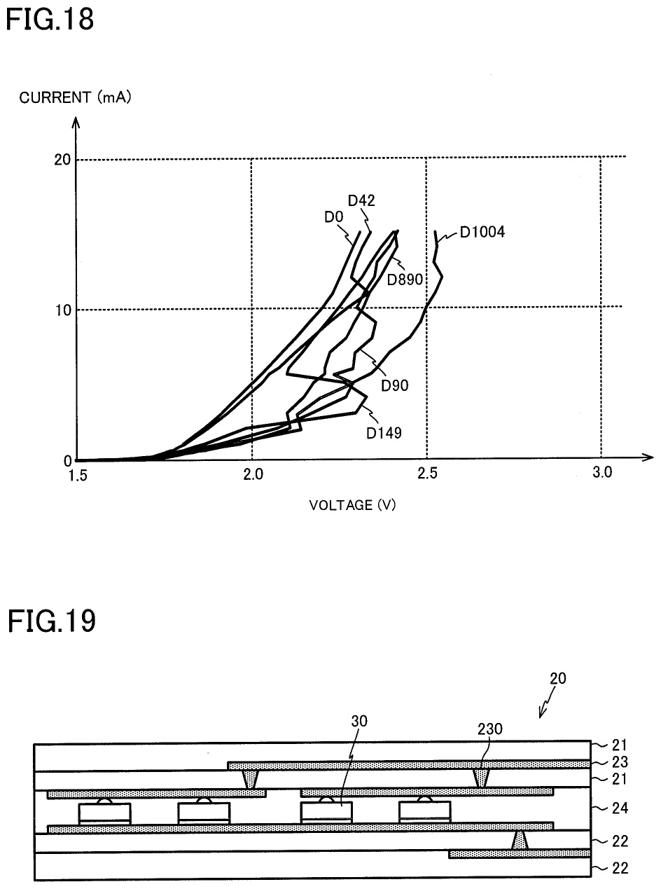

FIG. 17 is a diagram to show the current-voltage characteristics of the light emitting devices 10A to 10D after 1004 cycles in the thermal cycle test. Curves A4 to D4 show the current-voltage characteristics of the light emitting devices 10A to 10D, respectively. FIG. 18 is a diagram to show the current-voltage characteristics of the light emitting device 10D after 0 to 1004 cycles in the thermal cycle test. Curve DO shows the current-voltage characteristic before the temperature cycle test was started. Curve D42 shows the current-voltage characteristic after 42 cycles. Curve D90 shows the current-voltage characteristic after 90 cycles. Curve D149 shows the current-voltage characteristic after 149 cycles. Curve D890 shows the current-voltage characteristic after 890 cycles. Curve D1004 shows the current-voltage characteristic after 1004 cycles.

<<Verification of Measurement Results>>

Referring to FIG. 15 that shows the results of the high-temperature and high-humidity test, all of the light emitting devices 10A to 10C ran for 1000 hours, without a failure, even at a junction temperature Tⱼ of 130° C. By contrast with this, with the light emitting devices 10D, a device was seen to fail at a junction temperature Tⱼ of 130° C. To allow the light emitting devices 10D to run for 1000 hours without a failure, the temperature of light emitting elements needs to be 120° C. or lower.

Also, with the light emitting devices 10E, devices were seen to fail when the junction temperature Tⱼ was 110° C. To allow the light emitting devices 10D for 1000 hours without a failure, the temperature of light emitting elements needs to be 100° C. or lower.

With the light emitting devices 10, when a current of a practical value is supplied to the light emitting elements 30₁ to 30₈, the junction temperature of the light emitting elements 30₁ to 30₈ becomes approximately 110° C. or higher, up to 130° C. When a current smaller than the current corresponding to the junction temperature of 110° C. is supplied, the amount of light from the light emitting elements becomes insufficient. The current corresponding to the junction temperature of 130° C. is greater than the rated current of the light emitting element.

Consequently, it is likely that the resin E of the light emitting device 10E, having a junction temperature below 110° C., is not suitable for the resin sheet 241 to constitute a light emitting device 10. Furthermore, currents of practical values can be supplied to the light emitting devices 10A to 10D having junction temperatures of 110° C. or higher. Therefore, it is likely that the resins A to D constituting the light emitting devices 10A to 10D are suitable for light emitting devices 10, and it is likely that resins A, B and C are particularly suitable for light emitting devices 10. Given the above, it naturally follows that, in order to fulfill the performance of the light emitting device 10, the insulator 24 needs to be made of the resins A to D.

Curves A1 to E1 shown in FIG. 12 show the temperature dependency of the tensile storage elastic modulus of the insulators 24A to 24E used for the light emitting devices 10A to 10E. Also, curves A2 to E2 shown in FIG. 13 show the temperature dependency of the loss tangent tan δ in the dynamic viscoelasticity of the insulators 24A to 24E used for the light emitting devices 10A to 10E.

As shown in FIG. 12 and FIG. 13, with the insulators 24A, 24B, 24C and 24D, the tensile storage elastic modulus decreases by about two to three digits before and after the temperature at which the loss tangent tan δ becomes the maximum, but, from the room temperature to the temperature at which the loss tangent tan δ becomes the maximum, the tensile storage elastic modulus is less dependent on temperature. In addition, at and above the temperature at which the loss tangent tan δ becomes the maximum, again, the loss tangent tan δ is less dependent on temperature, and shows the value of 1×10⁶ Pa or greater. On the other hand, with the insulator 24E, the tensile storage elastic modulus keeps decreasing in all regions from −60° C. to 200° C., due to the rise of temperature, and, when 130° C. is reached, the tensile storage elastic modulus shows the value of 1×10⁶ Pa or greater.

As shown in FIG. 12, regarding the insulators 24A, 24B, 24C and 24D that fulfill the performance of light emitting devices 10, the tensile storage elastic modulus at 0° C. is 1.0×10⁹ Pa or greater, up to 1.0×10¹⁰ Pa, and the tensile storage elastic modulus at 130° C. is 1.0×10⁶ Pa or greater, up to 6.0×10⁸ Pa. It then follows that the tensile storage elastic modulus of the insulators of the light emitting devices 10 is preferably in the above range. Also, it is more preferable if the tensile storage elastic modulus at 130° C. of the insulators 24A to 24D is 2.0×10⁶ Pa or greater. Note that the upper limit of the tensile storage elastic modulus may be 6.0×10⁸ Pa or greater.

The light emitting device 10A with the insulator 24A has the highest tensile storage elastic modulus at the maximum junction temperature of the light emitting element, which is about 130° C., and has no problem in both the high temperature and high humidity test and the thermal cycle test. However, although the resin sheet 241 for forming the light emitting device 10A with the insulator 24A has high heat resistance after curing, does not discolor even after the test, and is excellent in processability, it is still a special resin and is very expensive.

On the other hand, the resin sheets 241B, 241C, 241D, and 241E are relatively inexpensive general-purpose resins. Among these, the light emitting devices 10B and 10C showed results that were comparable to those of the light emitting device 10A in the high temperature and high humidity test and the thermal cycle test.

Considering the above results, with the insulator 24, the tensile storage elastic modulus at about 130° C. should be 6×10⁸ Pa or less, preferably 2×10⁸ Pa or less.

As shown in FIG. 13, the temperature at which the loss tangent tan δ becomes the maximum in the insulators 24A, 24B, 24C, 24D, and 24E is 135° C., 115° C., 69° C., 28° C., and 117° C., respectively. When the high-temperature and high-humidity test is conducted, it is not preferable if the tensile storage elastic modulus changes significantly around the junction temperature of light emitting elements, and therefore the temperature at which the loss tangent tan δ of the insulator 24 becomes the maximum is preferably 20° C. or higher and lower than 130° C., and, more preferably, 40° C. or higher and lower than 120° C.

As can be seen from FIG. 16 showing the results of the thermal cycle test, with the light emitting devices 10A, 10B, 10C, and 10D, none of the light emitting devices was turned off even after more than 1000 cycles. However, as can be seen by comparing curve D4, which shows the current-voltage characteristics of the light emitting device 10D shown in FIG. 17, with curves A4, B4 and C4 of the light emitting devices 10A to 10C, the light emitting device 10D suggested a possibility of unstable current-voltage characteristics.

As shown in FIG. 18, with the light emitting device 10D, before the thermal cycle test, the current increases regularly, following the increase of the voltage, as shown with curve DO. However, once the thermal cycle test is started, the relationship between the voltage and the current becomes irregular. Consequently, it is possible to say that the light emitting devices 10A, 10B, and 10C have the highest reliability.

As shown in FIG. 15, in the high-temperature and high-humidity, the light emitting devices 10A to 10D, in which the insulators 24 are made of the resins A to D, show good results. Also, as shown in FIG. 14, when the humidity is changed from 40% to 85% in which the temperature is 85° C., the expansion coefficients of the resins A to D of the light emitting devices 10A to 10D are less than 10%. Therefore, the expansion coefficient of the insulator 24 of the light emitting device 10 is preferably less than 10% when the humidity is changed from 40% to 85% in an environment in which the temperature is 85° C. Furthermore, the expansion coefficient of the insulator 24 is more preferably 4.23% or less.

As shown in FIG. 14, the water-absorption coefficients of the resins A to D of the light emitting devices 10A to 10D are 0.10% or higher in an environment in which the temperature is 85° C. and the humidity is 85%. Therefore, the water-absorption coefficient of the insulator 24 of the light emitting device 10 needs to be 0.10% or higher in an environment in which the temperature is 85° C. and the humidity is 85%. Also, the water-absorption coefficients of the insulator 24 is preferably 0.15% or higher, and, more preferably, 0.3% or higher.

Now, although embodiments of the present invention have been described above, the present invention is by no means limited to the embodiments described above. For example, with each of the above-described embodiment, light emitting devices 10 that each have eight light emitting elements 30 have been described. This is by no means limiting, and each light emitting device 10 may have nine or more light emitting elements, or have seven or fewer light emitting elements. Furthermore, light emitting elements 30 of varying standards, such as ones that emit lights of different colors, can be used in a mixed manner.

The above-described embodiment have assumed that a light emitting module 20 has a pair of insulators 21 and 22, an insulator 24 that is formed between the insulators 21 and 22, and eight light emitting elements 30₁ to 30₈ that are arranged inside the insulator 24. This is by no means limiting, and, for example, as shown in FIG. 19, a light emitting module 20 may be comprised of a plurality of insulators 21 and 22, a multi-layer circuit that is made of conductor layers 23, which are formed on the respective surfaces of the insulators 21 and 22 connected by vias 230 formed in via-holes, and light emitting elements 30 that are electrically connected to the multilayer circuit. In this case, by using light emitting elements that have electrodes on the upper surface and the lower surface as light emitting elements 30, the circuit can be easily multi-layered.

Furthermore, light emitting elements to have electrodes on the upper surface and the lower surface can be used for light emitting devices with a single-layer conductor circuit like the light emitting device 10 shown in FIG. 1.

In this case, a second conductor layer 23 may be formed on the surface of the insulator 22.

Cases have been described with the above embodiments where the conductor layer 23 is made of metal. This is by no means limiting, and the conductor layer 23 may be made of a transparent conductive material such as ITO.

Cases have been described with the above embodiments where an insulator 24 is formed, with no gap, between insulators 21 and 22. This is by no means limiting, and the insulator 24 may be formed between the insulators 21 and 22 only partially. For example, the insulator 24 may be formed only around the light emitting elements. Also, for example, as shown in FIG. 20, the insulator 24 may be formed so as to constitute spacers to surround the light emitting elements 30.

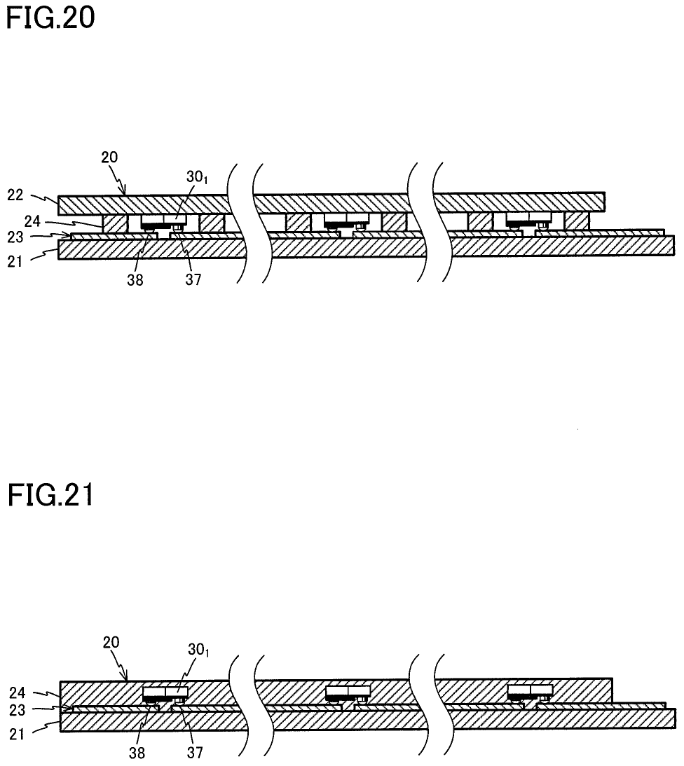

Cases have been described with the above embodiments where the light emitting module 20 of a light emitting device 10 has insulators 21 and 22 and an insulator 24. This is by no means limiting, and, as shown in FIG. 21, the light emitting module 20 may be comprised only of an insulator 21 and an insulator 24 that holds light emitting elements 30.

According to the above embodiments, a light emitting device 10 has an insulator 21, on which a conductor layer 23 is formed, and a light emitting element 30, with a pair of electrodes 35 and 36 formed on one surface, namely the upper surface. This is by no means limiting, and a light emitting device 10 may have an insulator with conductor layers formed on surfaces that oppose each other, and a light emitting element with electrodes formed on both upper and lower surfaces.

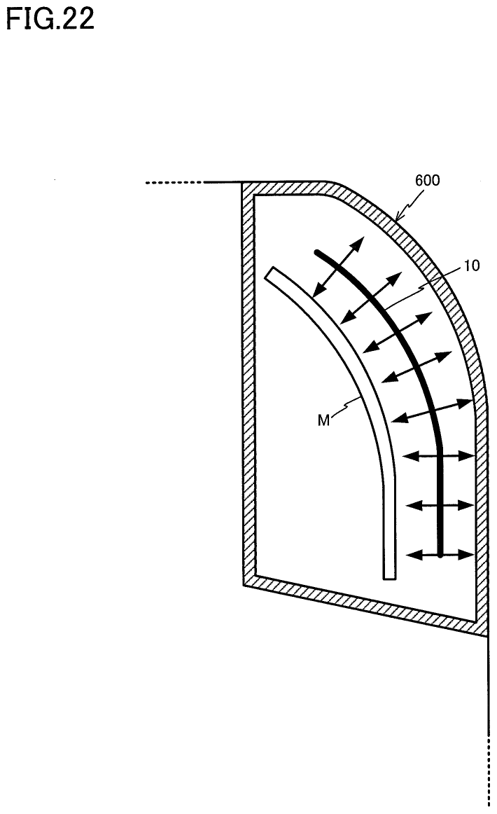

The light emitting devices 10 according to the herein-contained embodiments can be used for tail lamps for an automobile. By using a transparent and flexible light emitting module 20 as a light source, a variety of visual effects can be produced. FIG. 22 is a diagram to show, schematically, a cross-section of a resin casing in a horizontal plane, and its internal structure, with respect to a tail lamp 600 for an automobile. The light emitting device 10 is arranged along the inner surface of the resin casing of the tail lamp 600, and a mirror M is arranged on the back surface of the light emitting device 10, so that light that is emitted from the light emitting device 10 toward the mirror M is reflected by the mirror M, and then passes through the light emitting module 20, and is emitted to the outside. By this means, a unit that is configured as if having a light source apart from the light emitting device 10 in the depth direction of the tail lamp 600 can be formed.

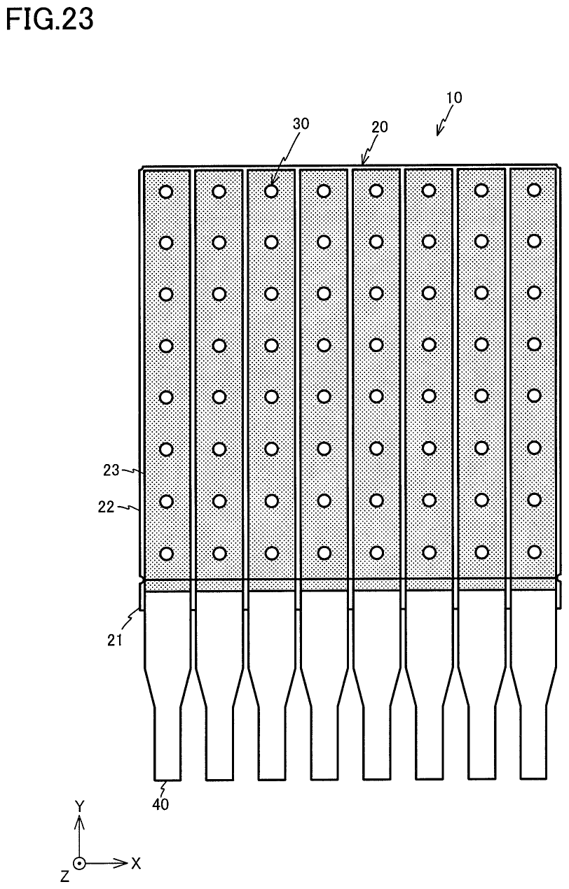

The light emitting devices 10 according to the above-described embodiments have assumed that the light emitting elements 30 are arranged on a straight line as shown in FIG. 4. This is by no means limiting, and, for example, as shown in FIG. 23, the light emitting elements 30 may be arranged in a matrix shape on a two-dimensional plane.

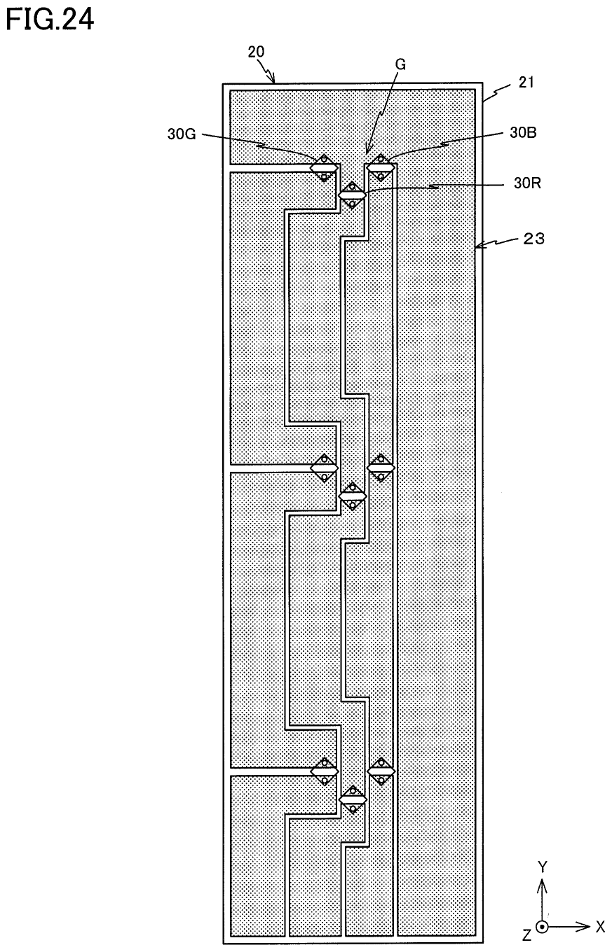

The light emitting module 20 of the light emitting device 10 according to the above embodiments, as shown in FIG. 4, the light emitting elements 30 are arranged apart from each other. This is by no means limiting, and, for example, as shown in FIG. 24, a light emitting element 30R that glows red, a light emitting element 30G that glows green, and a light emitting element 30B that glows blue may be arranged close, so as to form a light emitting element group G, and arranged apart from each other so that the light emitting element group G is recognized as a single bright spot.

Although embodiments of the present invention has been described above, the thickness of the insulator 24 according to the embodiments is also disclosed in detail in US Patent Application Publication No. US2016/0155913 (WO2014156159). The bumps 37 and 38 provided in the light emitting element 30 are also disclosed in detail in US Patent Application Publication No. 2016/0276561 (WO/2015/083365). How to connect between the conductor layer 23 and the flexible cable 40 is disclosed in detail in US Patent Application Publication No. US2016/0276321 (WO/2015/083364). The mesh pattern to constitute the conductor layer 23 is disclosed in detail in US Patent Application Publication No. 2016/0276322 (WO/2015/083366). The method of manufacturing the light emitting module 20 is disclosed in detail in US Patent Application Publication No. US2017/0250330 (WO 2016/047134). As shown in FIG. 23, a light emitting device in which light emitting elements are arranged in a matrix shape is disclosed in detail in Japanese Patent Application No. 2018-164963. The electrical connection between the bumps 37 and 38 and the conductor layer 23 in the light emitting device is disclosed in detail in Japanese Patent Application No. 2018-16165. Furthermore, the physical properties of the insulator 24 such as mechanical loss tangent are disclosed in detail in Japanese Patent Application No. 2018-164946. The contents disclosed in each of the above applications are incorporated herein by reference.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A light emitting device, comprising:
a first insulator, which is transparent to light;
a first conductor layer, which is provided on a surface of the first insulator;
a second insulator, which is transparent to light and arranged to oppose the first conductor layer;
a light emitting element, which is arranged between the first insulator and the second insulator, and connected to the first conductor layer; and
a third insulator, which is transparent to light and arranged between the first insulator and the second insulator,
wherein a tensile storage elastic modulus of the third insulator is 1.0×10⁹ Pa or greater, up to 1.0×10¹⁰ Pa, at 0° C., and 1.0×10⁶ Pa or greater, up to 6.0×10⁸ Pa, at 130° C.

2. A light emitting device comprising:
a first insulator, which is transparent to light;
a first conductor layer, which is provided on a surface of the first insulator;
a second insulator, which is transparent to light and arranged to oppose the first conductor layer;
a light emitting element, which is arranged between the first insulator and the second insulator and connected to the first conductor layer; and
a third insulator, which is transparent to light and arranged between the first insulator and the second insulator,
wherein, after a thermal cycle test, in which one minute of exposure in an environment with a temperature of 25° C., five minutes of exposure in an environment with a temperature of −40° C., one minute of exposure in the environment with the temperature of 25° C., and exposure in an environment with a temperature of 110° C. are carried out every five minutes, is performed 100 times, in a state in which the light emitting element is unlit, the light emitting element can be lit.

3. The light emitting device according to claim 2, wherein, after a thermal cycle test, in which one minute of exposure in an environment with a temperature of 25° C., five minutes of exposure in an environment with a temperature of −40° C., one minute of exposure in the environment with the temperature of 25° C., and exposure in an environment with a temperature of 110° C. are carried out every five minutes, is performed 1000 times, in a state in which the light emitting element is unlit, the light emitting element can be lit.

4. The light emitting device according to claim 1, wherein a plurality of light emitting elements are arranged between the first insulator and the second insulator.

5. The light emitting device according to claim 4, wherein the plurality of light emitting elements comprise a first light emitting element and a second light emitting element, which are both based on different standards.

6. The light emitting device according to claim 5, wherein:
a plurality of light emitting element groups comprising the first light emitting element and the second light emitting element are formed; and
the light emitting elements to constitute the light emitting element groups are arranged so as to be recognized as a single bright spot.

7. The light emitting device according to claim 1, further comprising a second conductor layer, which is provided on a surface of the second insulator, wherein the light emitting element is connected to the first conductor layer and the second conductor layer.

8. The light emitting device according to claim 1, wherein the tensile storage elastic modulus of the third insulator is 2.0×10⁶ Pa or greater, up to 2.0×10⁸ Pa, at 130° C.

9. The light emitting device according to claim 1, wherein a temperature at which mechanical loss tangent of the third insulator becomes maximum is 20° C. or higher, up to 130° C.

10. The light emitting device according to claim 9, wherein the temperature at which mechanical loss tangent of the third insulator becomes maximum is 20° C. or more and lower than 117° C.

11. The light emitting device according to claim 1, wherein, when a humidity is changed from 40% to 85% in an environment in which a temperature is 85° C., an expansion coefficient of the third insulator is less than 10%.

12. The light emitting device according to claim 1, wherein a water-absorption coefficient of the third insulator is 0.1% or higher in an environment in which a temperature is 85° C. and a humidity is 85%.

13. The light emitting device according to claim 1, wherein, in an environment in which a temperature is 85° C. and a humidity is 85%, the light emitting element keeps lighting for 1000 hours or longer in a state in which the light emitting element is bent along a circle having a radius of 50 mm.

14. The light emitting device according to claim 1, wherein an electrode of the light emitting element is connected to the conductor layer via a bump provided on the electrode.

15. A method of manufacturing a light emitting device, comprising the steps of:
forming a conductor layer on one side of a first insulator, which is transparent to light;
arranging an insulating sheet on one side of the first insulator and the conductor layer;
positioning an electrode of a light emitting element on a pad of the conductor layer, and mounting the light emitting element on the sheet;
arranging a second insulator, which is transparent to light, on one side of the light emitting element; and
heating and pressing a composite of the first insulator, the second insulator, the sheet and the light emitting element, under vacuum,
wherein a tensile storage elastic modulus of the sheet is 1.0×10⁹ Pa or greater, up to 1.0×10¹⁰ Pa, at 0° C., and 1.0×10⁶ Pa or greater, up to 6.0×10⁸ Pa, at 130° C.
